(19) United States
(12) Patent Application Publication
(10) Pub. No.: US 2010/0289550 A1
(43) Pub. Date: Nov. 18, 2010

(54) ELECTRONIC CIRCUIT FOR THE TRANSMISSION OF HIGH-FREQUENCY SIGNALS

(75) Inventors: Gunter Unterborsch, Berlin (DE); Christoph Leonhardt, Berlin (DE); Jorg Honecker, Berlin (DE)

Correspondence Address: SCHWEGMAN, LUNDBERG & WOESSNER, P.A., P.O. BOX 2938, MINNEAPOLIS, MN, 55402, US

(73) Assignee: U2T PHOTONICS AG, BERLIN (DE)

(21) Appl. No.: 12/530,090

(22) PCT Filed: Mar. 10, 2008
(86) PCT No.: PCT/EP08/02016

§ 371 Date: Aug. 3, 2010

(30) Foreign Application Priority Data
Mar. 8, 2007 (DE) 10 2007 012 29502

(51) Int. Cl. H03L 5/00

(52) U.S. Cl. 327/306

(57) ABSTRACT

The invention relates to an electronic circuit for transmitting high-frequency signals. Said electronic circuit comprises an amplification circuit featuring frequency-dependent amplification which remains the same or drops in a vicinity of a threshold frequency (fₜₕ) towards higher frequencies. The electronic circuit further comprises an equalizer circuit which is mounted behind the amplification circuit and has a frequency pass that increases in the vicinity of the threshold frequency (fₜₕ) towards higher frequencies.

The present invention relates to an electronic circuit for transmitting high-frequency signals, which comprises an amplification circuit with a frequency-dependent amplification, according to the preamble of the main claim.

Such an electronic circuit can involve for example a photoreceiver which is intended to be suitable for receiving high-frequency digital optical signals and for converting these optical signals into electrical signals. Because of the unavoidable property of the amplification circuits which are used in such electronic circuits of having a frequency-dependent amplification which drops, with higher frequencies, in the vicinity of a threshold frequency (if this is defined as lying in the range of a frequency band width of the amplification circuit), the problem occurs with generic electronic circuits according to the state of the art that signals which are characterised by high frequency components (beyond the mentioned threshold frequency) become greatly distorted. If such an electronic circuit is intended to be used for transmitting and amplifying extremely high-frequency digital signals, this can result in particular in rounding of the signals in the vicinity of steep edges, because of which possibly a differentiation can no longer be made between two different values of the digital signals. In the present document, the threshold frequency can be defined alternatively or at the same time also as a frequency of the order of magnitude of a high-frequency and typically digital signal to be transmitted, for example as half a value of a data transmission rate reached with the circuit. Even if the amplifier of a generic circuit at this threshold frequency still shows an amplification which remains constant with higher frequencies, undesired flattenings of signal edges can occur—for example due to dispersion effects in an optical transmission stretch—which can in turn make for example reading-out of a digital signal impossible.

The object therefore underlying the invention is to develop an equaliser circuit of the described type, with which flattening of signals with steep edges can be avoided at least to such an extent that it can also transmit digital signals in the vicinity of and if possible beyond the threshold frequency and thereby can still output them in readable form.

This object is achieved according to the invention by an electronic circuit having the characterising features of claim 1 in conjunction with the features of the preamble of claim 1. Advantageous embodiments and developments of the invention are revealed in the features of the sub-claims.

As a result of the fact that the electrical circuit has, in addition to the amplification circuit, an equaliser circuit which is connected subsequently to the amplification circuit, i.e. one which is connected by circuit technology to an output of the amplification circuit, said equaliser circuit having a frequency pass which increases, with higher frequencies, in the vicinity of the threshold frequency, the course of the frequency-dependent amplification of the amplification circuit which drops in the vicinity of the threshold frequency can be compensated for at least partially, as a result of which the electronic circuit, compared with the amplification circuit, is able to transmit higher-frequency signals of readable quality. Compared with a comparable electronic circuit without an equaliser circuit, significantly better eye diagrams are therefore produced by the present invention. The equaliser circuit may thereby be defined by the described function, the frequency pass being able to be defined such that an additional voltage drop caused by the equaliser circuit at one output resistor of the amplification circuit is taken into account as a property of the equaliser circuit.

A preferred embodiment of the invention provides that a part of the electronic circuit which comprises the amplification circuit and the equaliser circuit has a frequency-dependent amplification which remains constant or better still increases, with higher frequencies, in the vicinity of the threshold frequency. This can be achieved in that an equaliser circuit with a frequency pass which rises sufficiently steeply in the vicinity of the threshold frequency is chosen. A course of the frequency-dependent amplification, which drops with higher frequencies, of the electronic circuit which comprises the amplification circuit and the equaliser circuit is shifted consequently even with higher frequencies relative to the amplification circuit.

An embodiment of the electronic circuit is thereby particularly advantageous such that the frequency-dependent amplification of the part of the circuit which comprises the amplification circuit and the equaliser circuit rises, with higher frequencies, in the vicinity of the threshold frequency. It is then in fact achieved that a signal which diverges for example after passing through fairly long transmission stretches and/or is flattened in edge regions is transformed when passing through the amplification circuit such that it again obtains steeper edges. As a result, a further data transmission without information loss becomes in turn possible.

A typical embodiment of the invention correspondingly provides that the electronic circuit is suitable for transmitting high-frequency digital signals. It can be designed in particular such that it is suitable for a data transmission rate of approx. 40 Gbit/s or higher or even of approx. 100 Gbit/s or higher. In particular in this case, the mentioned threshold frequency can be in a range of between 15 GHz to 30 GHz, preferably in a range of between 20 GHz and 25 GHz. In these ranges, normal high-frequency amplifiers according to the state of the art reach a limit so that, in the case of an electronic circuit of the type proposed here which is defined via one of the mentioned ranges for the threshold frequency, the above-mentioned advantages of the invention can be exploited particularly effectively. In each case, the proposed design of the circuit with the equaliser circuit then leads to an advantageous compensation of flattening of signal edges. This advantageous effect is also revealed when the amplification circuit, even in the vicinity of the threshold frequency, still shows a constant frequency-dependent amplification, the proposed measures therefore not or not only serving for an increase in a transmission band width.

In a preferred embodiment of the invention the amplification circuit is a component of a photoreceiver, at least one light-sensitive element being connected before the amplification circuit. There can be used thereby as light-sensitive element for example a photodiode or a phototransistor. It is also possible that a plurality of photoreceivers is provided in front of an input or in front of a plurality of inputs of the amplification circuit. The amplification circuit can also comprise a plurality of amplifiers which are connected to each other and to the photoreceiver or to the photoreceivers. Typically, the amplification circuit will involve a current-voltage converter of the photoreceiver. However, it can also be provided by an amplifier which is connected subsequently to such a current-voltage converter. In conjunction with a photoreceiver, the proposed invention developed its advantages to particularly good account because signals transmitted by light, in particular optical digital signals, can experience rounding in an optical transmission and in a light-sensitive element receiving them, which make accurate amplification all the more important if no essential information is to be lost.

In order that the electronic circuit can fulfil its purpose of transporting high-frequency signals such that they become distorted as little as possible or at least remain readable, the equaliser circuit should have a dispersion-free effect or at least an extensively dispersion-free effect on signals input from the amplification circuit. Due to the frequency pass of the equaliser circuit which rises with higher frequencies, in fact a corresponding manipulation of a signal amplitude should therefore be effected, running time differences between signal components of different frequencies should in contrast be avoided. Equaliser circuits which can be produced without difficulty and still show satisfactory results in this respect can be configured for example such that they show, in a frequency range of between 0.5 fₜₕ and 1.5 fₜₕ, running time differences or phase shifts of at most λ/8, preferably at most λ/16, the threshold frequency being termed fₜₕ and the running time difference being expressed as phase angle difference of a signal of the respective frequency compared with the running time of a monofrequency reference signal at the mentioned interval. In the optimum case, electrical phases of output signals of the equaliser circuit—or at least relative phases between different frequency components—remain unaffected by the equaliser circuit.

A dispersion-free effect of the equaliser circuit and avoidance of undesired feedback effects can be achieved particularly easily if the equaliser circuit is configured as a passive circuit, i.e. contains only passive components. It is thereby harmless if a relatively small frequency pass in a frequency range below the threshold frequency altogether leads to attenuation of the signal passing through the electronic circuit because the problem underlying the invention is independent of an absolute amplitude of an output signal of the electronic circuit and, by avoiding flattening of steep edges, can also be resolved if, in total, attenuation or comparatively weaker amplification of the signal is effected.

A preferred embodiment of the invention provides that the equaliser circuit has an additional signal path which diverges from a main signal path, the main signal path connecting an output of the amplifier circuit to an output of the equaliser circuit. The desired effect of the equaliser circuit can then be achieved in that the signal path diverts a component, which reduces with higher frequencies, of a signal power which passes through the main signal path. The additional signal path thereby has preferably, apart from an input which is provided by a diversion on the main signal path, merely one output and in particular no feedback to the amplifier.

An embodiment of the invention which is particularly easy to produce provides that the additional signal path comprises an inductance and a resistor, but is configured advantageously without a capacitor in order to avoid reflection and dispersion effects. The resistor and the inductance can thereby be connected in series in a simple manner, as a result of which the inductance acts as a choke and can decouple the additional signal path with higher frequencies increasingly from the main signal path, whilst the resistor prevents too great an attenuation of the main signal at low frequencies.

In order that the equaliser circuit can develop its effect precisely in critical frequency ranges, the inductance can thereby be chosen for example with a value of between 0.1 nH and 3 nH and preferably have a value of between 1 nH and 1.5 nH. The inductance can be provided for example by a bonding wire or a strip conductor on a circuit carrier which carries at least one part of the electronic circuit. In order to avoid unnecessary stray capacitances, an element which produces the inductance should thereby preferably have no winding or only a few windings. In the case of production of the inductance by a bonding wire or a strip conductor, the bonding wire or the strip conductor, according to the thickness, can have for example a length of between 0.5 mm and 4 mm.

The resistor can be provided, in a preferred embodiment of the invention, by a surface-mounted device (SMD) or by a resistor layer integrated on a strip conductor. As a result, both a compact construction and avoidance of damaging long connection lines can be achieved.

In order to achieve, in the case of an amplification circuit with a normal output resistor, attenuation of lower-frequency components to a degree favourable for the desired effect, the additional signal path can be configured with an ohmic resistance of between 20Ω and 200Ω or between 50Ω and 200Ω, preferably between 70Ω and 150Ω.

In order to avoid undesired reflections and running time differences, the main signal path should contain no additional capacitor required for the equaliser circuit. Also the additional signal path should have no capacitor in order to avoid phase shifts. A capacitor can however be connected before or after as a component of a complete receiver stage of the equaliser circuit in order to ensure a direct current-free output.

In a particularly simple embodiment of the invention, the additional signal path can connect a diversion of the main signal path to a neutral conductor of the electronic circuit and in particular be connected for example to earth. As a result, an undesired feedback effect can be prevented particularly well.

For an altogether compact construction and avoidance of long connection lines which can have disturbing secondary effects, it can be advantageous to accommodate the entire electronic circuit in a single housing and/or on a common line carrier, which concerns normally a printed circuit board. According to the application, it can however be provided that a light-sensitive element which is connected before the amplification circuit is disposed outwith the housing or not on the same line carrier.

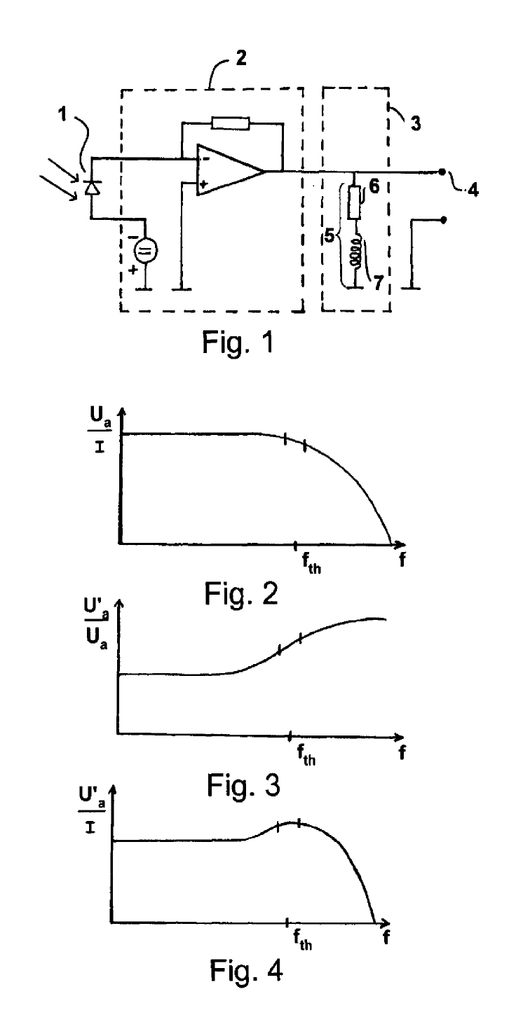

One embodiment is explained subsequently with reference to FIGS. 1 to 5. There are shown:

FIG. 1 a circuit diagram of an electronic circuit in a simple embodiment of the invention,

FIG. 2 as a diagram, a frequency-dependent amplification of an amplification circuit contained in the electronic circuit of FIG. 1,

FIG. 3 as a diagram, a frequency pass of an equaliser circuit contained in the electronic circuit of FIG. 1,

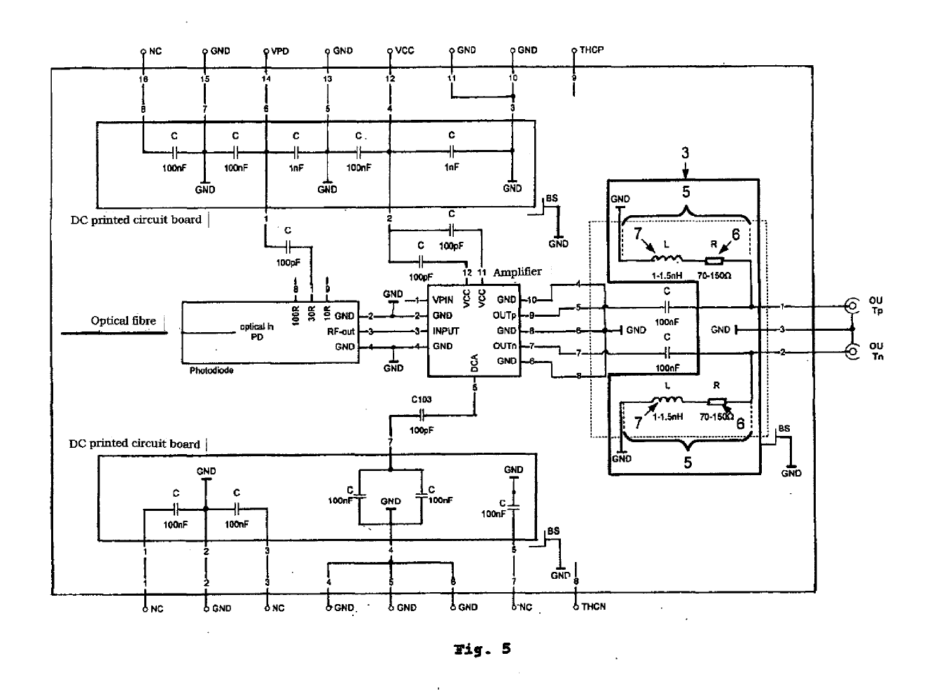

FIG. 4 in a diagram, a resulting frequency-dependent amplification of the electronic circuit of FIG. 1 and

FIG. 5 a circuit diagram of an electronic circuit in a different embodiment of the invention.

The electronic circuit illustrated in FIG. 1 has a light-sensitive element 1 configured as a photodiode, an amplification circuit 2 and an equaliser circuit 3 connected subsequently to the amplifier circuit 2. The light-sensitive element 1 is thereby connected before the amplification circuit 2 and connected to an input of the amplification circuit 2.

The amplification circuit 2 here concerns a simple current-voltage converter, the reproduced circuit diagram being able to be understood as equivalent circuit diagram which can be replaced by any other amplification circuits which are suitable for transmitting high-frequency digital signals. Also in the case of other embodiments of the invention, instead of the amplification circuit 2, a plurality of amplifiers which can be connected to each other and/or to further light-sensitive elements 1 can be provided.

The equaliser circuit 3 connected after an output of the amplification circuit 2 is configured as a passive circuit and, in addition to a main signal path which connects the output of the amplification circuit 2 to an output 4 of the electronic circuit, has an additional signal path 5 which diverges from this main signal path and connects the main signal path to a neutral line—typically identical to earth—of the electronic circuit. In the present embodiment, the additional signal path is thereby produced by a resistor 6 and an inductance 7 which are connected in series. The inductance 7 which is configured as an approx. 1 mm long bonding wire or as a strip conductor of the same inductance on a printed circuit board serving as circuit carrier thereby has a value of approx. 1 nH, whilst the resistor 6 configured as a surface-mounted device is dimensioned such that the additional signal path 5 has in total an ohmic resistance (direct current resistance) of approx. 100Ω. The bonding wire forming the inductance 7 or the strip conductor used alternatively to form the inductance 7 thereby has as straight a course as possible.

The main signal path of the equaliser circuit 3 in the illustrated embodiment is not guided through an additional capacitor, the equaliser circuit 3 also having no further path which includes capacitors.

The electronic circuit of the present embodiment is in a single housing and accommodated there on a common printed circuit board, on which, in addition to the resistor 6, also all the electronic components used for construction of the amplification circuit 2 are mounted, for example in the form of surface-mounted devices. In a slightly modified embodiment of the invention, the light-sensitive element can also be connected only indirectly to the printed circuit board and possibly accommodated in another housing.

It can be detected in FIG. 2 that a frequency-dependent amplification of the amplification circuit 2, which is defined here as the ratio of an amplitude Uₐ of an output voltage of the amplification circuit 2 to an amplitude I of an input current of the equaliser circuit 3, extends in the vicinity of a threshold frequency fₜₕ, which has here approximately a value of 20 GHz, dropping with higher frequencies.

In FIG. 3, a frequency pass of the equaliser circuit 3 is represented as a function of a frequency f. The frequency pass is defined here by the ratio of an amplitude Uₐ′ of an output voltage to the amplitude Uₐ, a voltage drop at an internal resistor or output resistor of the amplification circuit 2 being not yet deducted from the amplitude Uₐ. FIG. 3 shows that the frequency pass of the equaliser circuit 3 rises, with higher frequencies, in the vicinity of the threshold frequency fₜₕ. The equaliser circuit 3 is thereby configured such that it has a virtually dispersion-free effect on signals input from the amplification circuit 2.

The frequency-dependent ratio Uₐ′/I, shown in FIG. 4, illustrates a resulting frequency-dependent amplification of the electronic circuit of FIG. 1 with the equaliser circuit 3 connected subsequently to the amplification circuit 2. It can be detected that this resulting frequency-dependent amplification has a course which rises, with higher frequencies, in the vicinity of the threshold frequency fₜₕ, which is produced by attenuation in a low frequency range so that the electronic circuit, compared with the amplification circuit 2, shows an amplification drop shifted with higher frequencies, which makes it suitable for transmission of particularly high-frequency digital signals. A vicinity of the threshold frequency fₜₕ for which the above-mentioned applies is made evident in FIGS. 2 to 4 by way of example by two markings which delimit the vicinity.

The present invention here confers advantages in particular in conjunction with optical information systems in which information is transmitted by means of light. During signal processing, the light is converted by a photoreceiver into electrical signals in order subsequently to process the transmitted information further.

The photoreceiver, in a simple version, comprises a combination of one or more photodetectors and one or more subsequently connected electrical amplifiers which are accommodated in a housing and connected to each other. In the case of very high bit rates, it becomes increasingly more difficult to produce photoreceivers with a sufficiently high band width and simultaneously very high amplification. This has the following cause: the subsequently connected high-frequency amplifier is delimited in its frequency band width by the capacitance of the photodetector at its input. This capacitance acts as input impedance and, together with the feedback resistance of the amplifier which jointly determines the amplification, forms an RC module with an RC time constant. This RC module basically has a low-pass characteristic with a transmission function, the pass range of which extends from a lower boundary frequency (here 0) to an upper boundary frequency which is determined by the RC time constant. The achievable band width of the photoreceiver is hence determined. The photoreceiver will therefore often have only one still sufficient band width.

A high band width is necessary in order to keep the rise and drop time as short as possible in the case of a signal change from a logic zero to a logic one and vice versa. In the case of low bit rates (e.g. 1 Gbit/s), the transmitted optical signals (observed as functions of time) are relatively steep-edged and rectangular. The signals converted by the photoreceiver from the optical into the electrical range are therefore only slightly rounded as a result of the band-delimiting characteristic thereof. In the case of high bit rates, the optical input signals at the photoreceiver can however be already greatly rounded. If now the photoreceiver further rounds the signals, a significantly poorer quality and hence poorer reception sensitivity (higher image error rate) is obtained.

This problem is counteracted in the present invention by the equaliser circuit 3. The transmission function of the equaliser circuit 3 acts in such a manner that signals at a lower frequency than the threshold frequency fₜₕ are attenuated but signals of higher frequencies remain unaffected. For the combination of photoreceiver and equaliser circuit 3, higher frequency components relative to the lower ones are hence raised so that, during the transmission, in particular of pulses or bit sequences, the edge steepness of the signals (as functions of time) can be significantly improved.

As a result, significantly better eye diagrams and hence better reception sensitivity are produced. The degree of lowering of the signal at lower frequencies and a boundary frequency, in which the signal is no longer noticeably affected, can be determined by choice of the elements of the equaliser circuit 3 and hence be adapted to the photoreceiver or also to the behaviour of the transmission stretch in an optimum manner. The described equaliser circuit does not affect the phase and hence the group running time of the signal. Hence the signal is not additionally distorted as a function of time. By lowering the lower frequency components of the signal, the noise components in this range are also reduced and hence the proportion of the total noise level relative to the photoreceiver without an equaliser circuit.

In the simplest version of the invention, the equaliser circuit 3 can have a purely passive construction. In the case of more complex circuits, the necessary transmission function can be jointly integrated directly in a limiter-amplifier circuit which is connected subsequently to the photoreceiver. A simple passive variant of the equaliser circuit 3 is based on diverting, behind the photoreceiver, a proportion of the electrical signal via an additional signal path 5 (impedance path, here with resistor 6 and inductance 7), as a result of which dampening of the main path (main signal path) of a desired strength is affected. In the case of higher frequencies, the impedance path is decoupled via the inductance 7 so that the main path remains unaffected. Negative effects in the phase or group running time of the signal by additional passive components in the main path are hence avoided. Parasitic effects due to reflections in the impedance path are not taken into account.

The photoreceiver with one or more photodetectors and one or more subsequent amplifiers for digital optical data transmission with high bit rates converts incoming optical signals into electrical signals. In order to increase the steepness of the edges of the electrical signals, the equaliser circuit 3 is built into the signal path after the O/E conversion and increases the proportion of the high frequencies relative to low frequencies in the output signal. The equaliser circuit 3 is adjustable so that the ratio of the frequency components can be controlled. The phase and group running time of the signal remains unaffected. Extending the circuit for positive influencing of the phase is also conceivable. Hence, it becomes possible to compensate extensively for the dispersion of the optical transmission stretch in order to increase the steepness of the edges even further.

The modified signal follows changes more rapidly as a result. Hence, the period of time in which the signal is present at the level to be detected increases. A subsequent decision circuit has therefore more time and consequently makes fewer errors. Hence the bit error rate drops. It is hence also possible to extend the transmission stretch, which flattens the edges of the signal due to dispersion, at a constant bit error rate.

The equaliser circuit 3 thereby operates such that it diverts lower frequencies up to the threshold frequency fₜₕ partially via the additional signal path 5 and hence dampens the main signal in these frequencies. This takes place without affecting the phase of the output signal since otherwise the running time difference of different frequency groups increases and the widening of the eye which is achieved according to the O/E conversion is destroyed.

In the case of the described electronic circuit, in particular an optical transmission system STM 256/OC-768 or higher can be involved.

The equaliser circuit 3 preferably comprises an impedance network with a frequency-dependent resistor component. The non-frequency-dependent resistor of the impedance network controls the ratio of the signal component diverted via the additional signal path 5 relative to the remaining component of the signal in the main path. Hence dampening of the main signal is adjusted. The smaller the resistance value, the greater is the dampening. The frequency-dependent resistor ensures that mainly frequencies below fₜₕ pass through the additional signal path 5 and hence are dampened in the main path. The frequency-dependent resistor in contrast exceeds, for frequencies above the threshold frequency fₜₕ the value of the non-frequency-dependent resistance significantly so that high frequencies cannot pass through the additional signal path 5. With networks of a higher order, the transmission function of the equaliser circuit 3 can be adapted such that the sensitivity of the photoreceiver is optimised. The mentioned impedance network preferably comprises resistors 6 and inductances 7.

In contrast to other circuits, a part of the signal amplitude is hereby consciously sacrificed. This loss in amplification and hence in output level is acceptable since the limiting factor for the reception sensitivity with the described data rates is not the amplitude but the quality of the signal (defined by its form as a function of time).

The equaliser circuit 3 operates, in the simplest embodiment of the invention, such that it diverts lower frequencies up to a threshold frequency fₜₕ partially via the parallel additional signal path 5. The equaliser circuit 3 therefore comprises the resistance 6 and the inductance 7 as connection to earth. The value of the resistance 6 controls the ratio of the signal component diverted via the parallel signal path 5 relative to the remaining component of the signal in the main path. Hence the dampening of the main signal is adjusted. The smaller the resistance 6, the stronger is the dampening. The inductance 7 is connected in series to the resistor 6 and ensures that preferably frequencies below fₜₕ pass through the parallel signal path 5 and hence are dampened in the main path. The frequency-dependent resistance of the inductance 7, for frequencies above fₜₕ, significantly exceeds the value of the resistance 6 so that high frequencies cannot be diverted to earth.

The method can also be used on the transmitter side in order to preform the signal to be transmitted. After transmission over a possibly fairly long stretch, an optimised signal is obtained again for the photoreceiver. It is conceivable for example to incorporate the equaliser circuit 3 in a pre-amplifier or a driver circuit for the electrical modulation of a transmitter in order hence to influence the transmission characteristic line as described above.

A circuit diagram, explained in detail, of another embodiment of the present invention is represented in FIG. 5. Recurrent features are provided again with the same reference numbers. The electronic circuit illustrated here also concerns a photoreceiver with amplifier for processing high-frequency digital optical signals. Here also, an amplifier circuit 2 is connected subsequently to a light-sensitive element 1 which is configured as a photodiode and to which, in this embodiment, optical data are supplied by means of an optical fibre 8. An equaliser circuit 3 connected after the amplification circuit 2 is accommodated on its own printed circuit board which carries in addition respectively one block capacitor for each of two outputs of the amplification circuit 2. For each of the two mentioned outputs of the amplification circuit 2, the equaliser circuit again has an additional signal path 5 with respectively one resistor 6 and an inductance 7 connected in series thereto. The equaliser circuit 3 hence acts—apart from the fact that two main signal paths are provided for respectively one of the outputs instead of a single main signal path—analogously to the above-described equaliser circuit 3 of FIG. 1. The illustrated circuit finally includes also two DC printed circuit boards 9 which serve for decoupling from a supply network.

During the transmission of digital signals over a transmission stretch, for example by means of a glass fibre or another light conductor, the result is distortion of the optical signals. A transmitted short optical pulse becomes typically wider and wider during the transmission due to optical dispersion, whilst its edge steepness reduces. Dampening of high frequency components of a Fourier transform of the pulse in the frequency space corresponds to this. In particular in long light conductors, this can lead to high bit error rates. In an electronic circuit of the type proposed here, such an optical signal is now converted by the light-sensitive element into an electrical signal which firstly shows the same dampening of higher frequency components.

When the now electrical signals pass through the proposed equaliser circuit, the distortion associated with the described dampening of high-frequency components is compensated for. In the just-described embodiment, this takes place by dividing low-frequency signal components onto a main path and a subsidiary path—here the additional signal path 5. Consequently, the result in the main path termed above also as main signal path is a power reduction in the low-frequency range. In the case of high frequencies, the division into both paths does not take place or practically no longer because the inductance 7 then has great impedance. High frequencies pass through the equaliser circuit therefore practically undampened. Hence, the pulses—plotted over time—become narrower again, their pulse edges become steeper. As a result, an improved resolution of the signals is obtained again by more precise differentiation of adjacent pulses. It is therefore possible to optimise, in the described manner, an optical receiver even for fairly long optical transmission stretches of e.g. one or more kilometres and to achieve also a dispersion compensation within specific limits. It is thereby also conceivable to undertake, after the described circuit, a conversion again into an optical signal in order to bridge a further optical transmission stretch.

1. An electronic circuit for transmitting high-frequency signals, comprising an amplification circuit with a frequency-dependent amplification which remains constant or drops, with higher frequencies, in the vicinity of a threshold frequency (fₜₕ), wherein
the electronic circuit comprises an equaliser circuit which is connected subsequently to the amplification circuit and has a frequency pass which rises, with higher frequencies, in the vicinity of the threshold frequency (fₜₕ).

2. The electronic circuit according to claim 1, wherein the amplification circuit is a component of a photoreceiver, at least one light-sensitive element being connected before the amplification circuit.

3. The electronic circuit according to claim 1, wherein the electronic circuit is suitable for transmitting high-frequency digital signals.

4. The electronic circuit according to claim 1, wherein a part of the electronic circuit which comprises the amplification circuit and the equaliser circuit has a frequency-dependent amplification which remains constant or increases, with higher frequencies, in the vicinity of the threshold frequency (fₜₕ).

5. The electronic circuit according to claim 1, wherein the threshold frequency (fₜₕ) is in the range of half of a data transmission rate of the electronic circuit.

6. The electronic circuit according to claim 1, wherein the equaliser circuit is a passive circuit.

7. The electronic circuit according to claim 1, wherein the equaliser circuit does not affect an electrical phase of an output signal of the equaliser circuit.

8. The electronic circuit according to claim 1, wherein the equaliser circuit has an additional signal path which diverges from a main signal path.

9. The electronic circuit according to claim 8, wherein the additional signal path comprises an inductance and a resistor.

10. The electronic circuit according to claim 9, wherein the resistor and the inductance are connected in series.

11. The electronic circuit according to claim 9, wherein the inductance has a value of between 0.1 nH and 3 nH.

12. The electronic circuit according to claim 9, wherein the inductance is provided by a bonding wire or a strip conductor.

13. The electronic circuit according to claim 9, wherein the resistor is provided by a surface-mounted device or an element integrated on a strip conductor.

14. The electronic circuit according to claim 8, wherein the additional signal path has an ohmic resistance between 20Ω and 200Ω.

15. The electronic circuit according to claim 8, wherein neither the main signal path of the equaliser circuit nor the additional signal path is guided within the equaliser circuit by an additional capacitor.

16. The electronic circuit according to claim 8, wherein the additional signal path connects a diversion of the main signal path to a neutral conductor of the electronic circuit.

17. The electronic circuit according to claim 1, wherein it or a part of the electronic circuit which comprises the amplification circuit and the equaliser circuit is accommodated in a single housing and/or on a common line carrier.

18. An electronic circuit, for transmitting high frequency signals, comprising:
an amplification circuit with a frequency-dependent amplification which remains constant or drops, with higher frequencies, in the vicinity of a threshold frequency (fₜₕ) is in a range of half of a data transmission rate of the electronic circuit, and wherein the amplification circuit is a component of a photoreceiver, at least one light-sensitive element being connected before the amplification circuit, and wherein a part of the electronic circuit which comprises the amplification circuit and the equaliser circuit has a frequency-dependent amplification which remains constant or increases, with higher frequencies, in the vicinity of the threshold frequency (fₜₕ);
a passive equaliser circuit, which is connected subsequently to the amplification circuit, and which has a frequency pass which rises, with higher frequencies, in the vicinity of the threshold frequency (fₜₕ), and which does not substantially affect an electrical phase of an output signal of the equaliser circuit, and wherein the equaliser circuit has an additional signal path that diverges from a main signal path, wherein the additional signal path comprises a series-connected resistor and inductance.

19. The circuit of claim 18, wherein neither the main signal path nor the additional signal path includes a capacitor.
